(19) United States
(12) Patent Application Publication
(10) Pub. No.: US 2022/0113775 A1
(43) Pub. Date: Apr. 14, 2022

(54) SUPPLYING DEVICE FOR SUPPLYING A SIGNAL AND/OR POWER TO AN EXTERNAL DEVICE AND METHOD FOR PROTECTING AN EXTERNAL DEVICE SUPPLIED WITH THE SIGNAL AND/OR POWER

(71) Applicant: Rohde & Schwarz GmbH & Co. KG, Munich (DE)

(72) Inventors: Sascha KUNISCH, Haibach (DE); Philipp WEIGELL, Baierbrunn (DE)

(21) Appl. No.: 17/067,586

(22) Filed: Oct. 9, 2020

(51) Int. Cl. G06F 1/26; G06F 1/3215; G06F 1/28

(52) U.S. Cl. CPC G06F 1/266; G06F 1/28; G06F 1/3215

(57) ABSTRACT

The invention regards a supplying device for supplying a signal and/or power to an external device and method for operating the same while protecting the connected external device. The device comprises an output terminal, a signal and/or power source connected to the output terminal, a processing unit configured to generate a control signal and supply the control signal to the signal and/or power source. Further, a storage unit stores a description of an allowed range of at least one characteristic of the signal and/or the power to be output. Via a feedback path, the processing unit is provided with a feedback signal comprising information on signal characteristics of the output signal and/or power. The supplying device further comprises a test signal generator generating a test signal to be superimposed to the output of the signal and/or power source, and the processing unit is configured to analyze the feedback signal with respect to the description of the allowed range and to generate in response to a probability of the output leaving the allowed range the control signal to cause the signal and/or power source to adapt the output signal and/or power depending on the analysis result.

### TECHNICAL FIELD

The invention regards a method and supplying device that allow to protect the connected external device which is supplied with a signal and/or power by the supplying device from consequences of a malfunction of the supplying device.

### BACKGROUND

During development of new devices or components, it becomes more and more common to use simulation techniques. Such simulation techniques allow a variety of different approaches to be analyzed with respect to their function. Nevertheless, at some point in the development of new devices or components it will be necessary to produce prototypes for the solutions found to be reasonable in the simulation process. Obviously, prototypes are very costly and testing the prototypes must be performed efficiently in order to avoid an unaffordable increase in development costs. This is the more important the shorter product cycles are. Thus, in order to be able to regularly provide customers with improved products it must be ensured that during testing of the prototypes damage of these expensive devices or components can reliably be avoided.

Often times such damage is caused by the device that supplies the prototype with signals and/or power. The characteristics of the output signals and/or power must reliably lie within a certain range, independently from the response of the connected device. The external device, hereinafter also called DUT (device under test), will evidently cause variations in load which in turn may cause that the supplying device is not able to precisely hold the target value of signal and/or an output power. Thus, the output signal and/or the output power may vary during testing or operation of the connected external device. On the other hand, such a variation of the input characteristics of the signal or power at the external device's side might cause damage of the connected device. As explained above this is particularly costly in case that the external connected device is a prototype.

Further, the supplying device namely a power source or signal generator, may also degrade in their performance. To avoid that the degradation in their performance, namely the reduced ability to precisely output signals and/or power as targeted, leads to damaging the connected external device, it is necessary to monitor characteristics of the output signal and/or power and react appropriately. Usually, this is achieved by connecting unknown load and measuring the reaction of the supplying device. in case that the supplying device is out of specification calibration becomes necessary. It may easily be understood that such manual operation, connecting and disconnecting a device to be tested and the known load, is time-consuming and should be avoided. However, increasing the time intervals at which the performance of the supplying device is monitored bears the risk that a drift in the output characteristics is not recognized early enough and operation of the supplying device outside its specification may lead to a damage of the connected external device.

It is therefore desirable to provide a supplying device for supplying a signal and/or power to an external device and a methods for providing a signal and/or power to the external device that allow to monitor the output characteristics and timely identify whether operating the connected external device with the device for supplying the signal and/or power can be performed safely.

### SUMMARY

Embodiments of the present invention advantageously address the foregoing requirements and needs, as well as others, by providing a supplying device for supplying a signal and/or power to an external device and a methods for providing a signal and/or power to the external device that allow to monitor the output characteristics and timely identify whether operating the connected external device with the device for supplying the signal and/or power can be performed safely. The present invention allows such a safe operation of the connected external device.

The supplying device according to the present invention comprises an output terminal to which the external device can be connected. Via the output terminal signal and/or power is supplied to the external device. It is to be noted that for the following explanations mainly the term “power” is used as a placeholder for “signal and/or power” for the sake of legibility of the following elaborations. However, except for passages where it is explicitly stated, use of the term “power” always refers to “signal” supplied by the inventive device to the connected external device as well. Further, in the following explanations the term “power supply” will be used whenever a supplying device for supplying the signal and/or power is meant. Thus, the power supply as used hereinafter is one example of such a supplying device, which may alternatively be a signal generator.

The power supply comprises a processing unit that is configured to generate a control signal based on which a signal source and/or power source (hereinafter also: source) included in the device is controlled. Further, the power supply comprises a storage unit in which a description of an allowed range of at least one characteristic of the device's output is stored. Such a description may be a data model defining the range of one or more of the characteristics of the devices output. It is to be noted that such a description may even consist of a plurality of sets of values for individual characteristics of the output signal or the output power, reflecting the fact that an allowed range for one characteristic may depend on an actual value of another characteristic of the same output signal.

In order to ensure that the output of the power supply cannot damage the connected external device, the output as supplied by the source is monitored. This is achieved by means of a feedback path established in the power supply and feeding back information on characteristics of the output power to the processing unit. Based on the received information included in the feedback signal, the processing unit is able to evaluate whether the current output lies within the allowed range by analyzing the feedback signal (or information derived therefrom) with respect to the description of the allowed range. Depending on the outcome of such an analysis the processing unit then generates the control signal. The analysis of the feedback signal is also performed when a test signal, generated in a test signal generator, is superimposed to the output of the source. The test signal corresponds to a load change caused by the connected external device but is generated internally in the power supply. Thus, the response of the power supply to a low change can be simulated and in case that the reaction of the power supply leads to an operation outside its specification or is expected to lie outside its specification, measures for protecting the connected external device can be taken. It is to be noted that the analysis may for example identify the probability that in the near future the output of the power supply might lie outside the specified range based on an analysis of the feedback signal even if the characteristics determined from the output of the power supply to currently fulfill the requirements of the specification. Such a conclusion may be made based on data that is gathered from other situations in which allow to identify a certain set of characteristics currently measured with a not allowed deviation of the power supply at a later point in time.

The control signal is supplied to the source of the signal and/or power to be output which, in response to the respective received control signal, adapts the output signal and/or power. Thus, the output of the supplying device is finally adapted on the basis of the analysis result. This leads to an improved protection of the connected external device, since deviation from an acceptable variation of the output characteristics can be determined from the analysis of the feedback signal with respect to the description of the allowed range. This analysis reveals when an undesired output characteristic occurs or is to be expected and the connected external device may be protected by avoiding such an output. The problem is to predict how the output of the supplying device may change in response to a changing load of the connected device. According to the invention such a situation is emulated by internally in the supplying device generating the test signal which is superimposed to the output signal and/or output power. The waveform of the superimposed test signal is chosen such that typical and realistic conditions of the operation of a connected external device are emulated. Since the outputs which results from such a superimposition of the load variation is monitored as described above, it can immediately be determined whether such a situation would lead to undesirable change in output characteristics.

According to one advantageous aspect, the device providing a signal and/or power to an external device may be equipped with an interface so that an adaptation of the description of the allowed range may easily be performed. The interface may either obtain the description of the allowed range from a user input or from a remote data source. Such a remote data source might be, for example, a database connected to the World Wide Web allowing distribution of a description to be stored in the storage unit from a central server of the manufacturer. The connected power supplies may thus benefit from data gathered by the manufacturer from a plurality of power supply units, and thus, the description of the allowed range may be adjusted and improved over time. On the other hand, manual input is very efficient in case that minor adaptations shall be performed. Thus, it is particularly preferred that the interface is not limited to one of the possibilities to input data into the device and store it in the storage unit.

Further, according to another aspect, the feedback signal may be pre-processed before the analysis is performed in the processing unit. Such a pre-processing can either be performed within the processing unit itself or before the feedback signal is supplied to the processing unit somewhere in the feedback path. Thus, a dedicated additional processing unit executing pre-processing of the feedback signal may be included in the feedback path.

Pre-processing the feedback signal may specifically include at least one of transforming the feedback signal into the frequency domain, differentiating the feedback signal and integrating the feedback signal. Such pre-processing of the feedback signal allows a more efficient computation when the feedback signal, or, to be more precise, the information included in the feedback signal, is analyzed with respect to the allowed range. It is to be noted that the description of the allowed range does not necessarily need to define absolute values of a certain characteristic/certain characteristics but may even define the change over time or the like. Thus, pre-processing the feedback signal reduces the computational effort for such an analysis.

Further, it is preferred that the control signal that is generated by the processing unit includes information suitable to cause the source of the signal to be output and/or the power to be output to be switched off, reduce the output level of the output signal and/or output power, or to reduce a crest factor of the output signal and/or output power. It is to be noted that the external device is connected throughout the entire process of generating a test signal, superimposing it to the output signal and/or output power supplying the feedback signal to the processing unit and generating the control signal in response to the result of the analysis. Thus, without the time-consuming change of the connections as known from the prior art, it is possible to estimate whether a load change of the connected external device leads to an undesirable output from the supplying device. Based on such an estimation the connected external device may be protected. In many cases it is not absolutely necessary that the output is switched off at all but a reduction that avoids an overvoltage, for example, may be sufficient. The information included in the control signal may therefore be dependent on the extent to which the estimated output leaves the allowed range or the probability that the power supply might operate outside its specification.

As the test signal does not exactly correspond to a load change caused by the connected external device, the amount of deviation estimated based on the superimposed test signal allows to predict the probability that operation of the connected external device leads to a signal output and/or power output of the supplying device leaving the allowed range. Thus, even before the operation of the connected external device might cause a critical condition, it is possible to pre-empt such risky situations based on the analysis of the feedback signal that results from the superimposed test signal.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various obvious respects, all without departing from the spirit and scope of the present invention. Accordingly, the drawing and description are to be regarded as illustrative in nature, and not as restrictive.

### BRIEF DESCRIPTION OF THE DRAWINGS

Exemplary embodiments of the invention are now further explained with respect to the drawings by way of example only, and not for limitation. In the drawings:

FIG. 1 is a schematic illustrating the influence of the test signal to the output signal and/or output power exploited by the present invention;

FIG. 2 is a block diagram of a system comprising the inventive device for supplying the signal and/or power to an external device and such an external device connected to the supplying device; and

FIG. 3 a simplified flowchart illustrating the steps according to the present invention.

### DETAILED DESCRIPTION

A supplying device for supplying a signal and/or power to an external device and a methods for providing a signal and/or power to the external device that allow to monitor the output characteristics and timely identify whether operating the connected external device with the device for supplying the signal and/or power can be performed safely, are provided. In the following description, for the purposes of explanation, numerous specific details are set forth in order to provide a thorough understanding of the invention. It is apparent, however, that the invention may be practiced without these specific details or with an equivalent arrangement. In other instances, well-known structures and devices are shown in block diagram form in order to avoid unnecessarily obscuring the invention.

A processor, unit, module or component (as referred to herein) may be composed of software component(s), which are stored in a memory or other computer-readable storage medium, and executed by one or more processors or CPUs of the respective devices. A module or unit may alternatively be composed of hardware component(s) or firmware component(s), or a combination of hardware, firmware and/or software components. Further, with respect to the various example embodiments described herein, while certain of the functions are described as being performed by certain components or modules (or combinations thereof), such descriptions are provided as examples and are thus not intended to be limiting. Accordingly, any such functions may be envisioned as being performed by other components or modules (or combinations thereof), without departing from the spirit and general scope of the present invention. Moreover, the methods, processes and approaches described herein may be processor-implemented using processing circuitry that may comprise one or more microprocessors, application specific integrated circuits (ASICs), field programmable gate arrays (FPGAs), or other devices operable to be configured or programmed to implement the systems and/or methods described herein. For implementation on such devices that are operable to execute software instructions, the flow diagrams and methods described herein may be implemented in processor instructions stored in a computer-readable medium, such as executable software stored in computer memory storage.

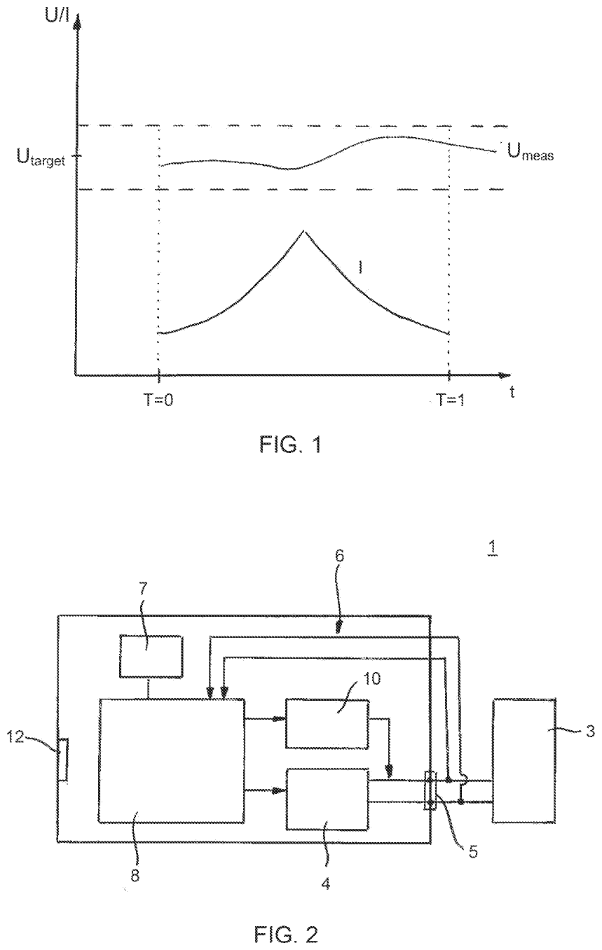

Before a block diagram of the inventive supplying device is explained with reference to FIG. 2, the principle of the present invention shall be explained. FIG. 1 shows a diagram in which a characteristic of the supplying device, in the illustrated embodiment the output voltage U, is measured and the measured characteristic is used as feedback signal. At a certain point in time Uₛₑₜ (T=0) the target value for the output voltage U_{target} is set. In an ideal scenario with a perfect power supply, this output voltage U would be constant over time (or follow a given curve of U_{target}) independent from the response of the connected external device. However, a change in the load that is connected to the power source will result in a variation of the output voltage U. As long as the variation of the output voltage is less than a range illustrated by the dotted lines dashed, the variation in output voltage may be considered as not critical for the connected external device.

According to the invention the power supply internally creates a test signal or test pulse, indicated in the drawing as changing current I over time, and superimposes the test signal to emulate a load change of the connected external device. The actual output voltage is monitored by sensing the voltage U and providing the sensed voltage to a processing unit. The sensed voltage is thus a feedback signal used in the processing unit for an analysis with respect to the definition of the range of allowed voltages. Since the variation of the output voltage is not the reaction to an actual load change of the connected external device but the response to the test signal, the measured characteristic of the output power only allows an estimation of a probability that the risk that the power supply is able to adjust the output to lie within the defined range when operating the connected external device.

If the analysis of the feedback signal measured as a response to the test signal reveals that there is a probability above a certain threshold that the output power might leave the allowed range, the processing unit generates a control signal causing a power source to react. In the diagram this will happen at the second point in time (T=1). At this point in time the output can be supplied to the connected external device in case that no risk can be determined that the output voltage will leave the allowed range. On the other hand, if there is significant risk that the output voltage might leave the allowed range, the generated control signal provided by the processing unit to the power source includes an information causing the power source to switch off, to reduce the output level or to reduce the crest factor. Instead of controlling the power source itself it is also possible to include a dedicated unit for adjusting the output supplied to the terminals connected to the power source, for example, a switch prohibiting any output to the connected external device in case that the control signal is a switch off signal.

The principle of the present invention is explained using the simple situation of providing an output voltage. However, it is evident that the same principle is applicable for more complex scenarios so that the allowed range is not only a one-dimensional interval but may define a plurality of characteristics of an output signal.

Coming now to FIG. 2 a scenario in which a power supply 2 as an example for the supplying device is used to provide a DUT 3 as an example for an external device with power. The power to be supplied to the DUT 3 is generated in a power source 4. The power source 4 is connected with an output terminal 5 of the power supply 2 to which the DUT 3 is connected.

For monitoring the output power, the power supply 2 comprises a feedback channel 6. The feedback channel feeds back information on the actual output of the power supply 2 to the DUT 3. The feedback signal is supplied to a processing unit 8, for example, a microprocessor. The feedback channel 6 is configured to sense characteristics of the output provided by the power supply 2 to the DUT 3. In the simplest configuration, the feedback channel 6 only forwards measured values of characteristics of the output and forwards the measurement result to the processing unit 8. The measurement itself may be performed outside the power supply 2.

For protecting the connected DUT 3, a test signal is generated in a test signal generator 10. The test signal generated in the test signal generator 10 is superimposed to the output of the source 4. Consequently, the adjustment of the output performed in response to the feedback signal now also takes account of the superimposed test signal. Since the test signal is generated to be close to actual changes of the load during operation of the DUT 3, the resulting adjustment of the output by the power supply 2 allows an estimation of responses during normal operation with a DUT 3 connected.

In the processing unit 8 an analysis of the feedback signal with respect to a description of an allowed range of one or more characteristics of the output is performed. Referring to the example illustrated in FIG. 2, the voltage U of the output is measured as a characteristic and analyzed with respect to the allowed range for the output voltage. Based on the results of the evaluation, the processing unit 8 generates a control signal which is supplied to the power source 4 and based on which the power source adjusts its output.

It is to be noted that the description of the allowed range does not necessarily need to be a set of thresholds that define an interval of allowed output values. It is also possible that the description defines sets of characteristics of the feedback signal that allow to conclude that the power supply 2 operates or will operate outside its specification. For example, the description may be a model allowing, based on artificial intelligence, to calculate a probability that the power supply 2 operates outside its specification based on a set of characteristics of the feedback signal. The calculated probability is then eventually compared with the threshold or the plurality of thresholds defining different escalation levels as a reaction to the actually measured output. The different escalation levels may be for example controlling the power source 4 to reduce the crest factor, reduce the output level and switch of output. The model may be generated based on training data. Alternatively, the model allows a direct comparison of characteristics of the output included in our being derivable from the feedback signal. In that case, the different thresholds may be defined by the amount of deviation from the target output.

The processing unit 8 may pre-process the feedback signal before the analysis is performed. Preferred pre-processing of the feedback signal is transforming the feedback signal into the frequency domain, differentiating or integrating the feedback signal. Such processing of the feedback signal is chosen according to a description of the allowed range of characteristics of the output.

This description of the allowed range is stored in a memory 7 as a storage unit, which is connected to the processing unit 8. The description may be stored in the memory 7 based on a user input provided by an interface 12. The interface 12 may also be configured to accept a user input setting the target output, for example, the target voltage. Further, the interface 12 may be configured to allow a connection of the power supply 22 a remote data source, for example, accessible via the World Wide Web.

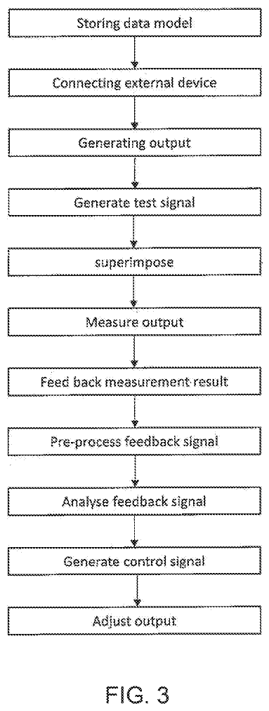

FIG. 3 shows a simplified flowchart of the method steps used to protect an external device connected to a power supply. In step S1 a data model comprising a description of the allowed range is stored in the memory 7. In step S2 the DUT 3 as external device is connected with the terminal 5 of the power supply 2. The source 4 generates the power output and supplies it via the terminal 5 to the DUT 3 in step S3. The output power is controlled based on a feedback signal used in the processing unit 8 for adjusting the power output by the source 4.

According to the invention, in step S4, the test signal generated by the test signal generator 10 is superimposed to the output of the source 4 in step S5. The output of the power supply 2 together with the superimposed test signal is measured instep as 6 and the corresponding feedback signal is forwarded to the processing unit 8 for feeding back the measurement result (step S7).

In the processing unit 8 or, alternatively, at an earlier position in the feedback path 6, pre-processing of the feedback signal may be performed (step S8). The feedback signal, or the pre-processed feedback signal, is then analyzed in step S9 and based on the results of the analysis a control signal is generated in step S10. Finally, the output of the power supply 2 is then adjusted in step S11 based on the generated control signal, which is supplied to the source 4.

As it has been demonstrated below the present invention allows to use a database, artificial intelligence or cloud-based calculation heuristic to determine the probability for safe operation of a supplying device when supplying signal or power to a connected external device. Using the internally generated test signal, superimposing it to the source output and then analyzing the output signal power with respect to a stored data model describing an allowed range of output characteristics allows at any time, having the external device connected to the supply device, to estimate whether the operation of such external device is risky or not. In response the calculated probability, for example, depending on comparison of the calculated probability with one or more thresholds, countermeasures may be taken. These countermeasures are chosen based on the comparison result of the calculated probability and the thresholds. The countermeasures are adaptations of the actual output of the power supply 22 the connected external device. Specifically, the adaptations may include one of switching off the output, limiting the output level and reducing the crest factor.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

1. A supplying device for supplying a signal and/or power to an external device, the supplying device comprising
an output terminal,
a signal and/or power source connected to the output terminal and configured to supply the signal and/or power to the output terminal,
a processor configured to generate a control signal and to supply the control signal to the signal and/or power source,
a storage device configured to store a description of an allowed range of at least one characteristic of the signal and/or power to be output,
a feedback path configured to supply the processor with a feedback signal comprising information on signal characteristics of the signal and/or power to be supplied to the output terminal,
a signal generator configured to generate a test signal and to superimpose the test signal on the output of the signal and/or power source,
wherein the processor is configured to generate the control signal by analyzing the feedback signal with respect to the description of the allowed range, wherein the control signal is configured to control the signal and/or power source to adapt the signal and/or power based on the analysis of the feedback signal, and
wherein the output terminal is configured to output the adapted signal and/or power to the external device.

2. The supplying device according to claim 1, wherein the processor or the feedback path is configured to pre-process the feedback signal.

3. The supplying device according to claim 2, wherein the pre-processing of the feedback signal comprises at least one of transforming the feedback signal into a feedback domain, differentiating the feedback signal and integrating the feedback signal.

4. The supplying device according to claim 1, wherein the supplying device comprises an interface configured to obtain the description of the allowed range from a user input device or a remote data source.

5. The supplying device according to claim 4, wherein the processor or the feedback path is configured to pre-process the feedback signal.

6. The supplying device according to claim 5, wherein the pre-processing of the feedback signal comprises at least one of transforming the feedback signal into a feedback domain, differentiating the feedback signal and integrating the feedback signal.

7. The supplying device according to claim 1, wherein the control signal is configured to control the signal and/or power source to switch off, to reduce an output level of the signal and/or power or to reduce a crest factor of the signal and/or power.

8. A method for protecting an external device connected to a supplying device configured to supply a signal and/or power to the external device, the method comprising:
storing a description of an allowed range of at least one characteristic of the signal and/or power to be output to the external device;
generating a test signal and superimposing the test signal on the signal and/or power;
providing a feedback signal to a processing device, wherein the feedback signal comprises information on signal characteristics of the signal and/or power;
analyzing the feedback signal with respect to the description of the allowed range;
generating a control signal configured to control a signal and/or power source to adapt the signal and/or power based on the analysis of the feedback signal; and
outputting the adapted signal and/or power to the external device via an output port of the supplying device.

9. The method according to claim 8, wherein the description of the allowed range is stored in the storage device based on a user input or based on information received from a remote data source.

10. The method according to claim 8, wherein the method further comprises:
pre-processing the feedback signal prior to the analysis of the feedback signal.

11. The method according to claim 10, wherein the pre-processing of the feedback signal comprises one or more of transforming the feedback signal into the frequency domain, differentiating the feedback signal and integrating the feedback signal.

12. The method according to claim 8, wherein the control signal is configured to control the signal and/or power source to switch off, to reduce an output level of the signal and/or power, or to reduce a crest factor of the signal and/or power.
